(19) United States
(12) Patent Application Publication
(10) Pub. No.: US 2016/0133837 A1
(43) Pub. Date: May 12, 2016

(54) Low-Temperature Deposition of Metal Silicon Nitrides from Silicon Halide Precursors

(71) Applicant: Intermolecular Inc., San Jose, CA (US)

(72) Inventors: Chien-Lan Hsueh, Campbell, CA (US); Randall J. Higuchi, San Jose, CA (US)

(21) Appl. No.: 14/539,054

(22) Filed: Nov. 12, 2014

(51) Int. Cl. H01L 45/00

(52) U.S. Cl. CPC H01L 45/1616; H01L 45/145

(57) ABSTRACT

Metal silicon nitride nanolaminates are formed at temperatures of 200-400 C by alternating ALD monolayers or thin CVD layers of metal nitride and silicon nitride. The silicon nitride layers are formed from a silicon halide precursor, causing nitrogen bonds to replace the halogen bonds, which is a lower-energy reaction than bonding nitrogen to elemental silicon. The silicon content, and thereby the resistivity, of the nanolaminate can be tuned by either a sub-saturation dose of the silicon halide precursor (forming ALD sub-monolayers) or by the relative number of metal nitride and silicon nitride layers. Resistivities between 1 and 500 Ω·cm, suitable for ReRAM embedded resistors, can be achieved. Some of the nanolaminates can function as combination embedded resistors and electrodes.

### BACKGROUND

Related fields include thin-film formation by atomic layer deposition (ALD), chemical vapor deposition (CVD), and related techniques; in particular, formation of ternary and higher-order silicon nitrides.

Advanced thin-film devices can only benefit from new materials if those materials can be reliably produced. Nitrides of mixed materials show promise, for example, in resistive-switching memory (sometimes called “ReRAM”) and in other applications.

Various nitrides have been considered for various components of ReRAM cells. While binary nitrides such as tantalum nitride and titanium nitride may be used in electrodes, ternary nitrides such as metal silicon nitrides (MeSiN) (wherein “Me” represents a generic metal and will be used throughout this discussion) are candidates for use as embedded resistors because of their stable performance and tunable resistance characteristics. However, deposition of MeSiN can be challenging because the reaction of ammonia (NH₃) with silane-family precursors (e.g., SiH₄, Si₂H₆, etc.) to form SiN requires process temperatures of 600-700 C, while many of the metal precursors react with NH₃ at 200-400 C but self-dissociate at 600-700 C. Thus, the process windows for the metal nitride (MeN) and silicon nitride (SiN) components of MeSiN may sometimes be mutually exclusive. In other instances, organic Si precursors may react with NH₃ at lower temperatures, but may leave carbon impurities in the layer that affect the electrical properties.

For example, consider tantalum silicon nitride (TaSiN). TaN with no Si is conductive—an electrode material—and the addition of Si raises the resistivity. With fairly high Si content, it works well as an embedded resistor in a ReRAM stack. However, the Si precursor tris(dimethylamino)silane (TDMAS) will only react with NH₃ to form SiN at a process temperature greater than 500 C, while the Ta precursor (tert-butylimido)tris(diethylamido)tantalum(V) (TBTDETa) self-dissociates at temperatures above about 340 C. This disparity in tolerable temperature range poses serious obstacles to conventional co-deposition.

Therefore, a need exists for a way to form high-Si metal silicon nitrides despite the disparities in reaction temperatures of the various components.

### SUMMARY

The following summary presents some concepts in a simplified form as an introduction to the detailed description that follows. It does not necessarily identify key or critical elements and is not intended to reflect a scope of invention.

Embodiments of methods for ALD and CVD formation of metal silicon nitride layers include a reaction between a nitridant and a silicon halide precursor. In this reaction, the halogen bond to Si is replaced with a nitrogen bond. This replacement requires much less energy than bonding N to elemental Si; the reaction may produce good-quality SiN, with no opportunity for carbon impurities, at temperatures between about 200 C and 400 C. This temperature range is well within the process window of many metal precursors.

In some embodiments, MeSiN deposition may include exposing a substrate to a pulse of a silicon halide precursor and a first pulse of nitridant to form a thin silicon nitride layer, followed by a pulse of a metal precursor and a second pulse of nitridant to form a thin MeN layer, and building up a nanolaminate of subsequent SiN and MeN layers until the desired MeSiN thickness is reached. For example, the desired MeSiN thickness may be 2-10 nm, a typical thickness range for ReRAM embedded resistors. In some embodiments, the thin SiN and MeN layers are ALD monolayers and the chamber is purged after each of the pulses. In some embodiments, the thin SiN and MeN layers are 1-2 nm CVD layers. Optionally, the topmost thin layer may be a SiN flash layer to prevent oxidation of the MeN during subsequent processes or air exposures. While forming the nanolaminate layers, the chamber pressure may be between about 0.1 Torr and 2 Torr.

For example, the silicon halide precursor may include SiF₄, SiCl₄, or SiI₄. The nitridant may be NH₃ or N₂H₄, and the nitridants used for the Si and the metal may be the same or different. The metal may be hafnium (Hf), lutetium (Lu), molybdenum (Mo), tantalum (Ta), titanium (Ti), tungsten (W), or zirconium (Zr).

Optionally, the SiN layers may be treated with a high-pressure hydrogen-containing gas to extract any trapped halogen atoms and expel them as hydrohalides (e.g., HF, HCl, HI). The hydrogen-containing gas may be forming gas (H₂—N₂ mix), hydrogen gas (H₂), or nitrogen gas (N₂); the pressure may be 100 Torr-2 atm; the temperature may be 300-400 C; and the duration may be 5-10 minutes.

The resistivity of the nanolaminate may be between 1 and 500 Ω·cm, as in some ReRAM embedded resistors. In some embodiments, the resistivity of the MeSiN layer may be controlled by selecting a pulse length or flow rate of a sub-saturation dose of the silicon halide precursor, so that the SiN forms a sub-monolayer rather than a saturated monolayer; this controls the density of SiN in each of the layers. In some embodiments, the resistivity of the MeSiN layer may be controlled by the ratio of SiN layers to MeN layers in the nanolaminate. Either approach can be used to create a gradient of Si concentration, and thereby resistivity, with depth. Such gradient layers may be used, for example, as combination electrodes (at the low-Si conductive interface) and embedded resistors (at the high-Si resistive interface).

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIG. 1 is a simplified block diagram of a resistive-switching non-volatile memory cell.

FIG. 2 is a conceptual graph illustrating temperature process windows for a pair of hypothetical precursors.

FIG. 3 is a block diagram of an example ALD or CVD apparatus.

FIGS. 4A-F conceptually illustrate ALD deposition of alternating MeN and SiN monolayers.

FIG. 5 is a conceptual example of a saturation curve for an ALD precursor dose.

FIGS. 6A-D conceptually illustrate some examples of ReRAM cells in which the distribution of MeN and SiN layers adjusts the Si content and distribution in the

FIG. 7 is a flowchart of an example process for constructing the MeN/SiN nanolaminate.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

As used herein, the following terms shall have the following meanings unless associated text or context indicates an exception:

“A,” “an,” and singular nouns: May include plural variations, e.g., “a layer” may mean “one or more layers.”

“About” or “approximately”: Within ±10% variation.

“Above” and “over”: Either directly contacting or separated by intervening elements; may conform to an underlying 3D structure.

“Between” (range of values): Both boundary values and any value between the boundaries can be within the scope.

“Chemical vapor deposition”: Depositing a film on a substrate from one or more vapor-phase chemical precursors that may be assisted to react by, e.g., heating the substrate.

“Constant resistance” (in a ReRAM embedded resistor layer): Resistance that remains approximately constant (e.g., ±25%) in response to either “read” or “write” signals.

“Dose”: For a gas (e.g., a precursor) or plasma, the product of pressure (P) in torr and time (t) in seconds; for light, the product of intensity (I) in W/cm2, averaged over the irradiated area, and time (t) in seconds.

“Film” and “layer”: Interchangeably describe a portion of a stack; may include multiple sub-layers (e.g., a nanolaminate).

“First,” “second,” and other ordinals: For differentiation only, rather than imposing any specific spatial or temporal order.

“Flash layer”: An ALD layer formed by pulsing a single precursor and heating the substrate to force the precursor to react with available reactants on or near the substrate surface.

“Horizontal”: In a plane parallel to the surface of a substrate. “Above,” “below,” “bottom,” “top,” “side” (e.g. sidewall), “higher,” “lower,” “upper,” “over,” and “under” are relative to the horizontal plane.

“Inert gas”: Includes noble gases (He, Ne, Ar, Kr, Xe) and, unless the text or context excludes it (e.g., by describing nitride formation as undesirable), nitrogen (N2).

“Metal nitride”: Comprising nitrogen and one or more metals or semiconductors.

“Monolayer”: A single layer of atoms or molecules covering a surface, with substantially all available bonding sites satisfied and substantially all individual members of the adsorbed species in direct physical contact with the underlying surface.

“On”: Directly contacting; may conform to an underlying 3D structure.

“Or” in a list: Any, all, or any subset of list may be used.

“Sub-monolayer” or “pre-wetting layer”: Partial or incomplete monolayer; maximum thickness is one atom or molecule, but not all available bonding sites on the surface are covered, so that the average thickness is less than one atom or molecule.

“Substantially”: Within up to ±5% variation.

“Substrate”: A wafer or any other workpiece on which formation or treatment of material layers is desired. Non-limiting examples include silicon, germanium, silica, sapphire, zinc oxide, SiC, AlN, GaN, Spinel, silicon on oxide, silicon carbide on oxide, glass, gallium nitride, indium nitride and aluminum nitride, glasses, combinations or alloys thereof, and other solid materials.

“Surface”: Boundary between the ambient environment and a feature of the substrate.

“Variable resistance” (in a ReRAM resistive-switching layer): Resistance that is reversibly switched between at least two stable states by “write” signals, but remains approximately constant in response to “read” signals.

FIG. 1 is a simplified block diagram of a resistive-switching non-volatile memory cell.

This is a non-limiting example of an application that could make use of metal silicon nitrides with high Si content; other applications could also use them.

Substrate 101 may include additional layers and structures beneath the memory cell. Electrodes 102 and 112 are conductive layers that may form contacts with the word-lines and bit-lines that select a particular cell in an array or group of other cells to read or write. Variable-resistance (VR) layer (or stack) 104 reversibly, repeatably switches between at least two stable states (e.g., low-resistance state R_{L} and high-resistance state R_{H}) in response to a “write” signal of an above-threshold energy transmitted through electrodes 102 or 112. For example, “write” signals may include a “set” signal that forms a conductive filament inside VR layer 104, producing the low-resistance state, and a “reset” signal that breaks, dissipates, or otherwise destroys the filament, returning the VR layer to the high-resistance state. In other types of memory, a write signal may change the phase, morphology, magnetic dipole, or some other electrical property of the VR layer or one or more of its interfaces. The “write” signal may be purely electrical, or may alternatively include a magnetic, thermal, or optical component. However, when a “read” signal is applied to sense the state of VR layer 104, its resistance does not change, generally because the “read” signal transfers only a sub-threshold energy to the layer. For example, the read signal may be a low voltage applied between the electrodes, resulting in a high output current if the VR layer's resistance is R_{L} or a low output current if the VR layer's resistance is R_{H}. The high and low output currents may be processed as logic “ones” and “zeroes” respectively.

A constant-resistance layer (or stack) 106, also known as an embedded resistor (ER), may be included in the cell to prevent excessive current from flowing through variable-resistance layer 104. For example, in cells that change their resistive state by forming and breaking conductive filaments, excessive current in a “set” signal could potentially create a filament so wide or dense as to be unbreakable by a normal “reset” signal. This would effectively lock the cell permanently in its low-resistance state, incapable of being overwritten. To prevent this, ER 106 acts like a non-variable resistor connected in series with the variable-resistance switch of VR layer 104, maintaining a constant resistance R_{C} (e.g., within ±25% or less) when either “read” or “write” signals are applied to the cell. Typical resistivity values for ERs in some metal-oxide ReRAM cells are on the order of 1-500 Ω·cm.

In addition, any number of intervening layers 103 may be formed between electrodes 102 and 112. Examples of intervening layers (or stacks) include barrier layers to prevent inter-layer reactions or diffusion of metals or oxides; buffer layers; defect-access layers; doping layers; coupling layers; diodes or other current-steering components; intermediate electrodes; and others.

It is believed that increased Si content may enable better performance of ER layers; for example, a higher-Si TaSiN may exhibit higher thermal stability and higher breakdown voltage than low-Si TaSiN. In addition, the option of increasing Si content may simplify fabrication by allowing some layers to be eliminated or others to perform multiple functions. For example, a TaSiN layer with a gradient distribution of Si could operate as an electrode (with low Si at the conductive-contact interface) and simultaneously as an ER (with high Si at the interface opposite the conductive contact). As another example, a gradient of HfOx to HfSiN could create an oxide VR layer with a built-in nitride ER.

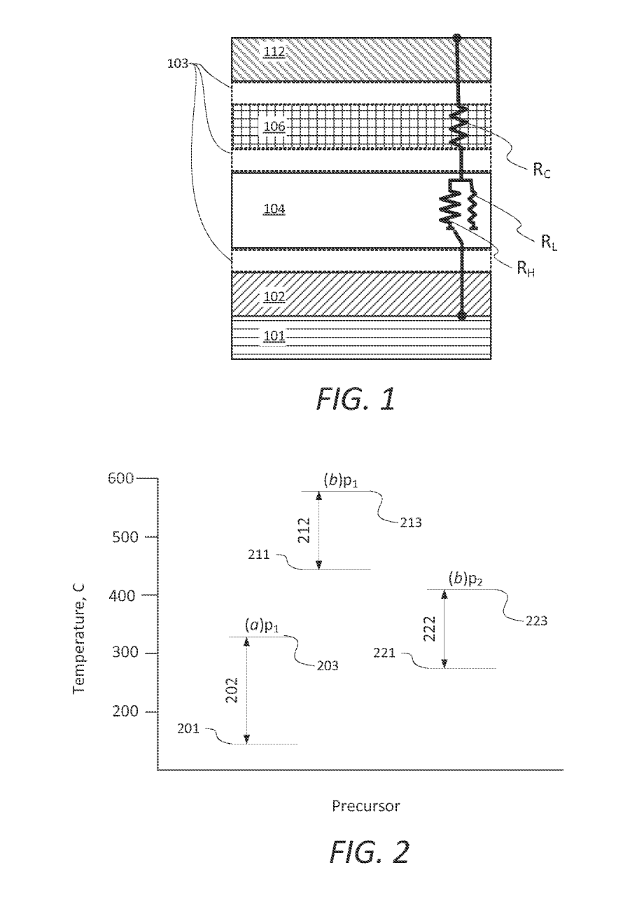

FIG. 2 is a conceptual graph illustrating temperature process windows for a pair of hypothetical precursors. A generalized ternary nitride can be expressed as (a)(b)N_{y} where (a) and (b) may be any suitable element other than nitrogen. In ReRAM applications, (a) and (b) are often metals, metalloids, semiconductors, or rare-earth elements.

In the illustrated example, a precursor (a)p₁ for material (a) does not produce the desired reaction with nitrogen below temperature 201 (T_{min, (a)p1}). It does react if the temperature is within range 202, and it dissociates, decomposes, or is otherwise compromised in its effectiveness of deposition or reaction above temperature 203 (T_{max, (a)p1}). Range 202 can be considered the “process window” for precursor (a)p₁. Meanwhile (b)p₁, a precursor for (b), does not react with nitrogen below temperature 211 (T_{min, (b)p1}), does react in its process-window range 212, and encounters problems above temperature 213 (T_{max, (b)p1}). For example, (a)p₁ may be a metal-organic precursor such as TBTDETa and (b)p₁ may be an inorganic precursor such as silane or disilane.

There is no temperature that is within both of the process windows 202 and 212; (a)p₁'s maximum temperature 203 is well below (b)p₁'s minimum temperature 211. Therefore, co-deposition of (a) from (a)p₁ and (b) from (b)p₁ is very difficult. In some instances, another precursor (e.g., (b)p₂ in FIG. 2) may be available that has a process window overlapping that of (a)p₁ and does not present obstacles of its own (e.g., excessive expense, toxicity, handling difficulty, or a tendency to leave impurities such as undetached carbon ligands in the layer). As illustrated, (b)p₂'s minimum temperature T_{min, (b)2} 221 is less than T_{max, (a)p1} 203, so between temperatures 221 and 203 (a)p₁ and (b)p₂ could be co-deposited.

Such a case applies to MeSiN precursors. The nitrogen reaction for metal precursors of interest for ER applications (e.g., Hf, Lu, Ir, Mo, Ta, Ti, W, or Zr precursors) has a low-temperature process window that does not overlap the high-temperature process window for nitrogen reaction with inorganic silanes, a common SiN precursor. Using the model of FIG. 2, the metal precursors would be like (a)p₁ and the silanes (e.g., silane, disilane, trisilane) would be like (b)p₁. By contrast, silicon halide precursors are like (b)p₂; the process window for their nitrogen reaction overlaps that for the metal precursors' nitrogen reaction between about 300 C and 400 C. This enables MeN and SiN to be formed together using ALD or CVD.

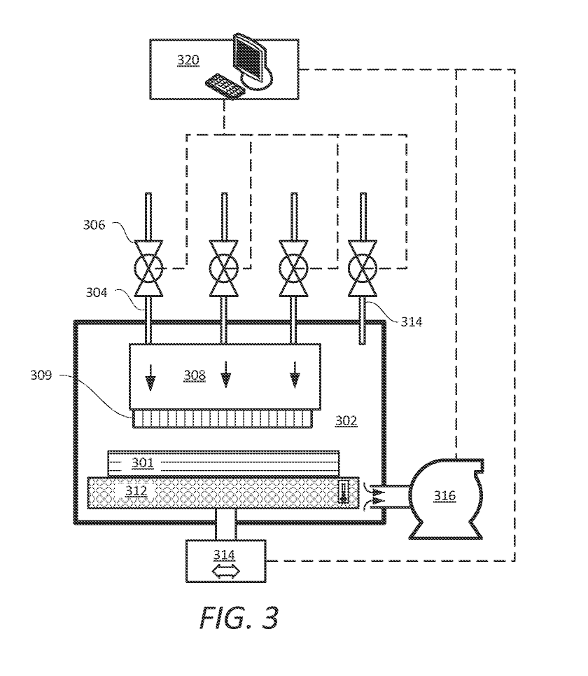

FIG. 3 is a block diagram of an example ALD or CVD apparatus. For clarity, some components of some types of ALD or CVD chambers, such as substrate-loading ports, substrate lift pins, and electrical feedthroughs, are not shown. Environmentally-controlled process chamber 302 contains substrate holder 312, which holds substrate 301 for processing. Substrate holder 312 may be made from a thermally conducting metal (e.g., tungsten, molybdenum, aluminum, nickel) or other materials such as conductive ceramic, and may be temperature-controlled. Drive 314 may move substrate holder 312 (e.g., translate or rotate it in any direction) during loading, unloading, process set-up, or sometimes during processing.

Process chamber 302 is supplied with process gases by gas delivery lines 304 and 314, of which any suitable number may be used. A valve or mass flow controller 306 may be connected to one or more of delivery lines 304 or 314 to control the delivery rates of process gases into process chamber 302. Gases may be routed from some delivery lines 314 directly into chamber 302 (e.g., noble or buffer gases), and from other delivery lines 304 through delivery port 308 (e.g., process gases). Delivery port 308 may be configured to premix the process gases (e.g., precursors and diluents), distribute the process gases over the surface of substrate 301, or both. Delivery port 308, sometimes called a “showerhead,” may include a diffusion plate 309 with multiple outlet holes to distribute the process gases. Meanwhile, vacuum pump 316 exhausts reaction products and unreacted gases from, and maintains the desired ambient pressure in, process chamber 302.

Controller 320 may be connected to control various components of the apparatus to produce a desired set of process conditions. Controller 320 may include one or more memory devices and one or more processors with a central processing unit (CPU) or computer, analog or digital input and output connections, motor controller boards, and the like. In some embodiments, controller 320 executes system control software including sets of instructions for controlling timing, gas flows, chamber pressure, chamber temperature, substrate temperature, radio frequency (RF) power levels (if RF components are used, e.g., for process gas dissociation), and other parameters. Other computer programs and instruction stored on memory devices associated with controller 320 may be employed in some embodiments.

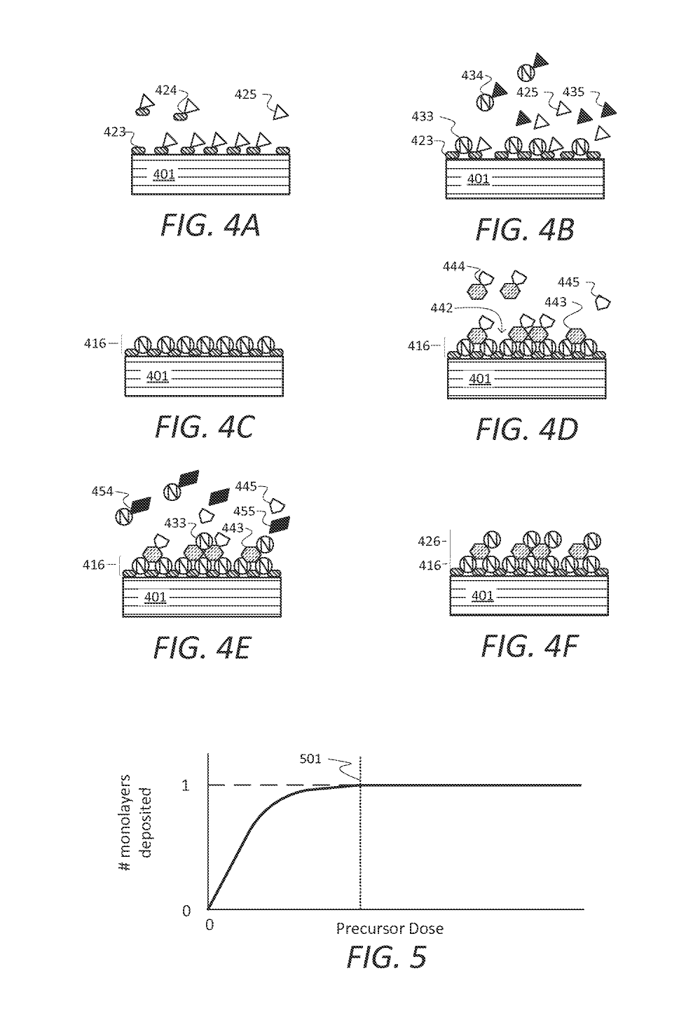

FIGS. 4A-F conceptually illustrate ALD deposition of alternating MeN and SiN monolayers. These illustrations are highly symbolic and not intended to accurately resemble any particular atoms or molecules. In FIG. 4A, substrate 401 (which may already include other structures such as an electrode or a VR layer) is exposed to metal precursor 424, which includes one or more metal atoms 423 and one or more ligands 425. Some of the ligands 425 may detach from metal atoms 423 when precursor 424 adsorbs to the substrate surface, or they may not. Precursor 424 is injected into the chamber for a predetermined length of time (“pulsed”), then the chamber is purged.

In FIG. 4B, substrate 401 is exposed to a pulse of a first nitridant 434, which includes one or more nitrogen atoms 433 and one or more ligands 435. Upon adsorption to the surface of substrate 401, nitridant 434 reacts with the adsorbed metal precursor 424 and/or metal 423 to form metal nitride. Ideally, all the ligands 425 and 435 are detached, and a subsequent purge removes them from the substrate and the chamber. Thus, as shown in FIG. 4C, a thin layer 416 (here, an ALD monolayer) of MeN is formed, beginning the fabrication of a layer such as the ER layer 106 of FIG. 1.

In FIG. 4D, substrate 401 is exposed to a pulse of Si precursor 444, which includes one or more silicon atoms 443 and one or more ligands 445. In some embodiments, ligand 445 may include a halogen such as fluorine, chlorine, or iodine. Some of the ligands 445 may detach from Si atoms 443 when Si precursor 444 adsorbs to the MeN layer on substrate 401, or they may not; in some embodiments, most of the halide ligands remain intact in the adsorbed Si precursor. The pulse of Si precursor 444 may be followed by a purge of the chamber.

In some embodiments, as shown here, the Si precursor pulse delivers a sub-saturation dose so that a sub-monolayer having gaps at some empty bonding sites 442, rather than a full monolayer with no gaps, adsorbs to the substrate. Alternatively, the Si precursor dose may be sufficient to deposit a full-coverage monolayer.

In FIG. 4E, substrate 401 is exposed to a pulse of a second nitridant 454, which includes one or more nitrogen atoms 433 and one or more ligands 455. Optionally, second nitridant 454 may be the same as first nitridant 434. Upon adsorption to the substrate surface, nitridant 434 reacts with the adsorbed Si precursor 424 and/or Si 423 to form silicon nitride. Ideally, all the ligands 445 and 455 are detached, and a subsequent purge removes them from the substrate and the chamber. Thus, as shown in FIG. 4F, a thin layer 426 (here, an ALD sub-monolayer, leaving gaps where there is no Si) of SiN is formed over the thin layer 416 of MeN, continuing the fabrication of a layer such as the ER layer 106 of FIG. 1. Because the layers are thin, the laminate of MeN and SiN layers has the electrical properties of MeSiN.

The resistivity of the nanolaminate may be between 1 and 500 Ω·cm, as in some ReRAM embedded resistors. The more Si in the nanolaminate, the higher the resistivity.

FIG. 5 is a conceptual example of a saturation curve for an ALD precursor dose. The dose, controlled by such variables as flow rate, pressure (or partial pressure of the precursor if there are other gases in the chamber), and pulse length, can produce at most one monolayer of material due to the self-limiting nature of ALD. Therefore, the Si precursor dose only varies the Si content in a MeSiN nanolaminate for dose values less than or equal to saturation point 501. Above the saturation point, the Si content is insensitive to the Si precursor dose.

Alternatively, the nanolaminate layers may be deposited by CVD rather than ALD. In some embodiments, the CVD layers may not be monolayers, but may be less than 10 or even 5 molecules thick (e.g., <1-2 nm). CVD does not self-limit, so there is no saturation dose beyond which the Si content becomes dose-insensitive.

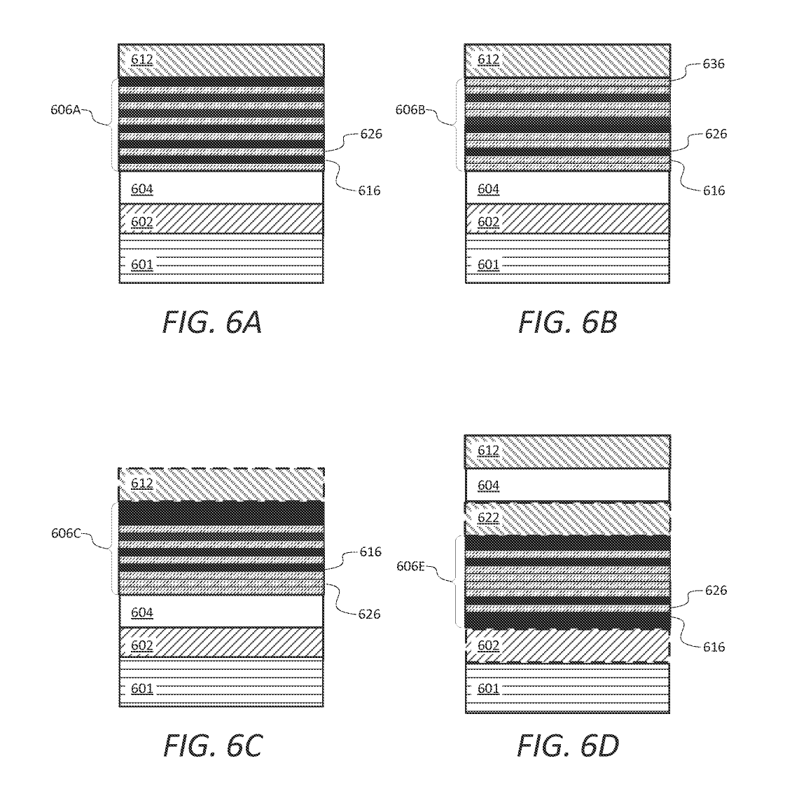

FIGS. 6A-D conceptually illustrate some examples of ReRAM cells in which the distribution of MeN and SiN layers adjusts the Si content and distribution in the nanolaminate. The layer distribution may be used as well as the Si precursor dose, or instead of it, to adjust the Si content in the MeSiN layer. In FIG. 6A, substrate 601 supports first electrode 602, VR layer (or stack) 604, ER nanolaminate 606A, and second electrode 612. Alternatively, ER 606 may be formed underneath VR 604. As shown, the MeN layers 616 and SiN layers 626 are alternating and uniformly distributed in ER 606A.

In FIG. 6B, ER 606B is more Si-rich than 606A because it has more SiN layers 626 than MeN layers 616. ER 606B also has a topmost SiN flash layer 636 to protect the underlying MeN from oxidation during annealing or transfer between process chambers.

FIG. 6C illustrates an example of a gradient ER 606C: more Si-rich near VR layer 604 to block oxygen diffusion (many VR layers are oxide materials) and more metal-rich near top electrode 612 for a more conductive contact. In some embodiments, the MeN-rich section of such a gradient layer (illustrated as the top section of the nanolaminate) may function as an electrode, so that separate electrode 612 may not be needed.

FIG. 6D illustrates a different type of gradient ER stack. ER layer 606E is between bottom electrode 602 and an intermediate electrode 622. For the desired high resistivity and conductive contacts to both electrodes 602 and 622, the MeN layers are concentrated near the electrode interfaces and the SiN layers are concentrated near the center of the ER stack. In some embodiments, MeN-rich sections of such a gradient layer (illustrated as the outer interfaces of the nanolaminate) may function as electrodes, so that separate electrodes 622 and/or 612 may not be needed.

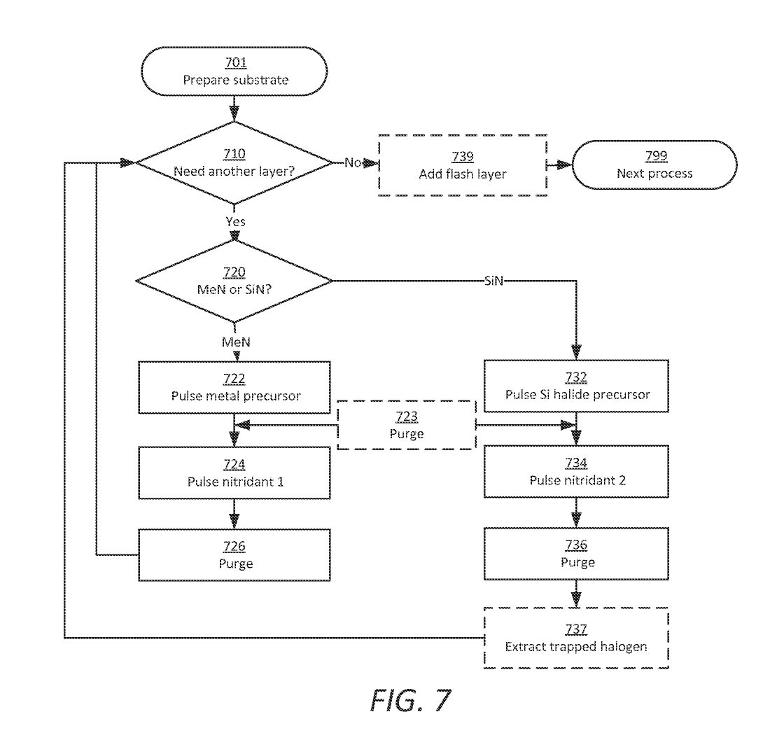

FIG. 7 is a flowchart of an example process for constructing the MeN/SiN nanolaminate. Step 701 of preparing a substrate may include cleaning, degassing, forming underlying layers or structures, or treating the underlying layers or structures. If, at decision 710, an additional nanolaminate layer is desired (which will be “Yes” for at least the first two layers), the process branches at decision 720 depending on whether a MeN layer or a SiN layer is to be formed.

Forming a MeN layer includes step 722 of pulsing a metal precursor, step 724 of pulsing a first nitridant, and step 726 of purging the chamber. In some embodiments (e.g., ALD processes), step 723 of purging the chamber may be added between metal precursor pulse 722 and first nitridant pulse 724. Alternatively, in some embodiments (e.g., CVD processes), the metal precursor and the first nitridant may be in the chamber simultaneously.

Forming a SiN layer includes step 732 of pulsing a silicon halide precursor, step 734 of pulsing a second nitridant, and step 736 of purging the chamber. In some embodiments (e.g., ALD processes), step 723 of purging the chamber may be added between silicon halide precursor pulse 732 and second nitridant pulse 734. Alternatively, in some embodiments (e.g., CVD processes), the silicon halide precursor and the second nitridant may be in the chamber simultaneously. Optionally, the pulse of silicon halide precursor may be a sub-saturation dose to form a sub-monolayer of SiN. In some embodiments, the second nitridant may have the same composition as the first nitridant. Optionally, step 737 of extracting trapped halogen ligands from the SiN layer may be inserted after purge 736.

After forming a MeN or SiN layer, the process returns to branch 710 to determine whether enough layers have been deposited to reach the desired thickness. If the desired thickness is reached, decision 710 is “No.” Optional step 739 of forming a flash layer may be inserted before next process 799 commences. Flash layer formation 739 may involve pulsing only the silicon halide precursor and heating the substrate in a range from about 200 C to about 500 C to force the precursor to react with available nitrogen in the nanolaminate. Next process 799 may include forming an overlying layer such as an electrode, a VR layer, or one of the intervening layers 103 from the discussion of FIG. 1. Alternatively, next process 799 may include a treatment such as patterning or annealing.

While forming the nanolaminate layers, the chamber pressure may be between about 0.1 Torr and 2 Torr and the substrate temperature may be 200-300 C. The metal may be hafnium (Hf), lutetium (Lu), molybdenum (Mo), tantalum (Ta), titanium (Ti), tungsten (W), or zirconium (Zr). The silicon halide precursor may include SiF₄, SiCl₄, or SiI₄. The nitridant may be NH₃ or N₂H₄. The pulse length may be between about 0.1 and about 1 second. The flow rate of the precursors and nitridants may be in a range between about 50 sccm and about 100 sccm. The trapped-halogen extraction treatment may include exposure to a hydrogen-containing gas such as forming gas (H₂—N₂ mix), hydrogen gas (H₂), or nitrogen gas (N₂) to extract any trapped halogen atoms and expel them as hydrohalides (e.g., HF, HCl, HI). The pressure of the hydrogen-containing gas may be 100 Torr-2 atm; the temperature may be 300-400 C; and the duration may be 5-10 minutes. The desired thickness may be 2-10 nm.

Precursors for the metals may include, without limitation:

Hf: (diethylamido) hafnium (TDEAHf), tetrakis(dimethylamido) hafnium (TDMAHf), tetrakis(ethylmethylamido) hafnium (TEMAHf) or hafnium chloride (HfCl₄).

Lu: lutetium(III) acetate hydrate (C₆H₉LuO₆.xH₂O), lutetium(III) acetate hydrate (C₁₅H₂₁LuO₆.xH₂O).

Mo: (bicyclo[2.2.1]hepta-2,5-diene)tetracarbonylmolybdenum(0) (C₁₁H₈MoO₄), bis(cyclopentadienyl)molybdenum(IV) dichloride (C₁₀H₁₀Cl₂Mo), cyclopentadienylmolybdenum(II)tricarbonyl, dimer (C₁₆H₁₀Mo₂O₆), molybdenumhexacarbonyl (Mo(CO)₆), propylcyclopentadienyl)molybdenum(I)tricarbonyl dimer (C₂₂H₂₂Mo₂O₆).

Ta: pentakis(dimethylamino)tantalum(V) (Ta(N(CH₃)₂)₅), tantalum(V) ethoxide (Ta(OC₂H₅)₅), tris(diethylamido)(tert-butylimido)tantalum(V) ((CH₃)₃CNTa(N(C₂H₅)₂)₃), tris(ethylmethylamido)(tert-butylimido)tantalum(V) (C₁₃H₃₃N₄Ta).

Ti: titanium(IV) chloride, titanium(IV) ethoxide, titanium(IV) i-propoxide, titanium(IV) n-butoxide, titanium(IV) t-butoxide, tetrakis(diethylamino)titanium(IV), cyclopentadienyl(cycloheptatrienyl)titanium(II), (trimethyl)pentamethylcyclopentadienyltitanium(IV), tris(2,2,6,6-tetramethyl-3,5-heptanedionato)titanium(III).

W: bis(butylcyclopentadienyl)tungsten(IV) diiodide (C₁₈H₂₆I₂W), bis(tert-butylimino)bis(tert-butylamino)tungsten ((C₄H₉NH)₂W(C₄H₉N)₂), bis(tert-butylimino)bis(dimethylamino)tungsten(VI) (((CH₃)₃CN)₂W(N(CH₃)₂)₂), bis(cyclopentadienyl)tungsten(IV) dichloride (C₁₀H₁₀Cl₂W), bis(cyclopentadienyl)tungsten(IV) dihydride (C₁₀H₁₂W), bis(isopropylcyclopentadienyl)tungsten(IV) dihydride ((C₅H₄CH(CH₃)₂)₂WH₂), cyclopentadienyltungsten(II)tricarbonyl hydride (C₈H₆O₃W), tetracarbonyl(1,5-cyclooctadiene)tungsten(0) (C₁₂H₁₂O₄W), triamminetungsten(IV)tricarbonyl((NH₃)₃W(CO)₃).

Zr: bis(cyclopentadienyl)zirconium(IV) dihydride (C₁₀H₁₂Zr), bis(methyl-η₅-cyclopentadienyl)methoxymethylzirconium (Zr(CH₃C₅H₄)₂CH₃OCH₃), dimethylbis(pentamethylcyclopentadienyl)zirconium(IV) (C₂₂H₃₆Zr), tetrakis(diethylamido)zirconium(IV) ([(C₂H₅)₂N]₄Zr), tetrakis(ethylmethylamido)zirconium(IV) (Zr(NCH₃C₂H₅)₄), zirconium(IV) diisopropoxidebis(2,2,6,6-tetramethyl-3,5-heptanedionate) (Zr(OCC(CH₃)₃CHCOC(CHCOC(CH₃)₃)₂(OC₃H₇)₂), zirconium tetrakis(2,2,6,6-tetramethyl-3,5-heptanedionate) (Zr(OCC(CH₃)₃CHCOC(CH₃)₃)₄)

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method, comprising:
placing a substrate in a chamber;
exposing the substrate to a pulse of a metal precursor;
exposing the substrate to a pulse of a first nitridant;
purging the chamber;
exposing the substrate to a pulse of a silicon halide precursor; and
exposing the substrate to a pulse of a second nitridant;
wherein the metal precursor and the first nitridant react to form a metal nitride layer having a thickness less than 2 nm;
wherein the silicon halide precursor and the second nitridant react to form a silicon nitride layer having a thickness less than 2 nm; and
wherein a process temperature for forming the metal nitride layer and the silicon nitride layer is between about 200 C and about 400 C.

2. The method of claim 1, wherein the metal nitride layer and the silicon nitride layer are formed by chemical vapor deposition.

3. The method of claim 1, wherein the metal nitride layer and the silicon nitride layer are formed by atomic layer deposition;
wherein the metal nitride layer and the silicon nitride layer are monolayers; and further comprising:
purging the chamber before the exposing of the substrate to the first nitridant, and
purging the chamber before the exposing of the substrate to the second nitridant.

4. The method of claim 1, wherein the metal nitride layer and the silicon nitride layer are formed by atomic layer deposition;
wherein the metal nitride layer comprises a monolayer and the silicon nitride layer comprises a sub-monolayer; and further comprising:
purging the chamber before the exposing of the substrate to the first nitridant, and
purging the chamber before the exposing of the substrate to the second nitridant.

5. The method of claim 1, wherein the metal nitride layer and the silicon nitride layer are formed by atomic layer deposition; and wherein the pulse of the silicon halide precursor constitutes a sub-saturation dose.

6. The method of claim 1, wherein the metal precursor comprises at least one of hafnium, lutetium, molybdenum, tantalum, titanium, tungsten, or zirconium.

7. The method of claim 1, wherein the silicon halide precursor comprises at least one of SiF₄, SiCl₄, or SiI₄.

8. The method of claim 1, wherein the first nitridant or the second nitridant comprises at least one of NH₃ or N₂H₄.

9. The method of claim 1, further comprising forming a silicon flash layer above the metal nitride layer and the silicon nitride layer.

10. The method of claim 1, further comprising exposing the silicon nitride layer to a hydrogen-containing gas at a pressure between 100 Torr and 2 atm and a temperature between 300 C and 400 C for a time between 5 minutes and 10 minutes.

11. The method of claim 10, wherein the hydrogen-containing gas comprises at least one of H₂, NH₃, or forming gas.

12. The method of claim 1, further comprising forming additional metal nitride layers or additional silicon nitride layers at a temperature between about 200 C and 400 C to form a nanolaminate of a desired thickness.

13. The method of claim 12, wherein the desired thickness is between about 2 nm and about 10 nm.

14. The method of claim 12, wherein a resistivity of the nanolaminate is between 1 Ω·cm and 500 Ω·cm.

15. The method of claim 12, wherein a distribution of the additional metal nitride layers and the additional silicon nitride layers is uniform throughout the nanolaminate.

16. The method of claim 12, wherein a distribution of the additional metal nitride layers and the additional silicon nitride layers varies with depth through the nanolaminate.

17. The method of claim 12, wherein a resistivity of the nanolaminate is different at a top surface than at a bottom surface.

18. The method of claim 12, wherein a local resistivity of the nanolaminate is different in a central region than at a top surface and a bottom surface.

19. The method of claim 12, wherein the nanolaminate is operable as an embedded resistor in a ReRAM cell.

20. The method of claim 12, wherein the nanolaminate is operable as a combination embedded resistor and electrode in a ReRAM cell.
